(19) United States
(12) Patent Application Publication
(10) Pub. No.: US 2002/0155676 A1
(43) Pub. Date: Oct. 24, 2002

(54) Zero mask MIMcap process for a low k BEOL

(76) Inventors: Michael Stetter, Fishkill, NY (US); Petra Felsner, Fishkill, NY (US); Andreas Augustin, Muenchen (DE); Gabriela Brase, Fishkill, NY (US); Andy Cowley, Wappingers Falls, NY (US); Gerald Friese, Fishkill, NY (US)

Correspondence Address: SLATER & MATSIL, L.L.P., 17950 PRESTON RD, SUITE 1000, DALLAS, TX, 75252-5793, US

(21) Appl. No.: 09/838,690

(22) Filed: Apr. 19, 2001

(51) Int. Cl. H01L 21/20; H01L 21/4763; H01L 21/8242; H01L 27/108; H01L 29/76

(52) U.S. Cl. 438/396; 438/393; 438/239; 257/306; 257/303

(57) ABSTRACT

A MIM capacitor (52) comprising a bottom plate (26), a capacitor dielectric (30) and a top plate (46). The capacitor bottom plate (26) is formed within an insulating layer (20) for a contact via (32) layer. The capacitor top plate (46) is formed within an insulating layer (34) of a metallization layer. The MIM capacitor (52) may be fabricated without the use of additional processes and patterning masks.

### TECHNICAL FIELD

The present invention relates generally to the fabrication of semiconductor devices, and more particularly to metal-insulator-metal (MIM) capacitors.

### BACKGROUND OF THE INVENTION

Semiconductors are widely used for integrated circuits for electronic applications, including radios, televisions and personal computing devices, as examples. Such integrated circuits typically use multiple transistors fabricated in single crystal silicon. It is common for there to be millions of semiconductor devices on a single semiconductor product. Many integrated circuits now include multiple levels of metallization for interconnections.

The manufacturing process flow for semiconductors is generally referred to in two time periods: front-end-of-line (FEOL) and back-end-of-line (BEOL). Higher temperature processes are performed in the FEOL, during which impurity implantation, diffusion and formation of active components such as transistors occurs. Lower temperature processes take place in the BEOL, which generally starts when the first metallization layer is formed. There is a defined thermal budget during the BEOL to prevent diffusion of metal into dielectric, and avoid flowing of the metal lines, which can cause voids and result in device failures. Exposing a semiconductor wafer to high temperatures, e.g., exceeding 400 degrees C., can also cause the impurities to move about.

For many years, aluminum has been used for the conductive material comprising the interconnect layers of semiconductor devices. Usually an aluminum alloy with a small amount of copper and silicon is used. For example, a prior art aluminum conductive alloy may comprise 2% silicon to prevent the aluminum from diffusing into the surrounding silicon, and 1% copper, to control electro-migration and lead breakage due to Joule's heat.

The semiconductor industry continuously strives to decrease the size and increase the speed of the semiconductor devices located on integrated circuits. To improve the speed, the semiconductor industry is changing from aluminum to copper for metallization layers. Copper has a low resistivity compared to aluminum, resulting in faster current capability when used as a conductive material. Also, the industry is moving towards using low-dielectric constant (k) materials as insulators between conductive leads and the various metallization layers to reduce the overall size of the semiconductor devices.

Using copper as the material for metallization layers has proven problematic for certain standard BEOL devices. One example is in the fabrication of MIM capacitors. MIM capacitors (MIMcaps) are used to store a charge in a variety of semiconductor circuits, such as mixed signal and analog products. Once a metallization layer has been applied, when copper is used, the semiconductor wafer cannot be exposed to temperatures higher than around 400° C., because the metallization system may be damaged at temperatures higher than this.

Prior art MIMcaps are manufactured in the BEOL by forming the bottom capacitive plate in the first or subsequent copper metallization layer of a semiconductor wafer. To achieve an adequate area capacitance, the top plate is typically formed by an additional metallization layer. Alternatively, to be independent of the quality of the metallization surface, MIMcaps can also be formed between metallization layers in the BEOL in additional layers. Because of the temperature limitations dealing with copper, the capacitor dielectric material is limited to those requiring temperature processing of 400° C. or less.

Furthermore, forming the bottom electrode of a MIMcap in a metallization layer requires an additional process or series of processes, e.g., metal deposition, patterning, and etch, to form the capacitor top plate. These processes require the use of additional masks, which increases the cost and time for production. For example, 2-3 masks and 2-3 lithography levels are currently required to manufacture prior art BEOL MIMcaps.

What is needed in the art is a MIMcap structure and method of fabrication thereof that allows a wider variety of materials to be used for the capacitor dielectric, and requires no or less additional processes or masks in the manufacturing process.

### SUMMARY OF THE INVENTION

These problems are generally solved or circumvented by the present invention, which achieves technical advantages as a MIMcap and method of fabrication thereof where the capacitor bottom plate is formed within a dielectric layer in which contact vias are formed. The capacitor top plate is formed in a metallization layer, thus requiring no additional mask or process steps to form the MIMcap.

Disclosed is a method of fabricating a MIMcap, comprising providing a workpiece having a substrate portion and a component portion, depositing a first insulating layer over the workpiece substrate portion, and etching the first insulating layer to simultaneously form a trench for a capacitor bottom plate over the workpiece substrate portion and form a hole for a via over the workpiece component portion. A conductive material is deposited to simultaneously fill the capacitor bottom plate trench and the via hole, wherein filling the via hole provides electrical contact to the workpiece component portion.

Also disclosed is a method of fabricating a MIMcap, comprising depositing a first insulating layer over a workpiece having a substrate portion and a component portion, and simultaneously forming a capacitor bottom plate over the workpiece substrate portion and a via over the workpiece component portion, the via providing electrical contact to the workpiece component portion. A capacitor dielectric is formed over the capacitor bottom plate, and a capacitor top plate is formed over the capacitor dielectric.

Further disclosed is a MIMcap comprising a workpiece having a substrate portion and a component portion, a first insulating layer disposed over the workpiece, and a capacitor bottom plate formed within the first insulating layer over the workpiece substrate portion. A via is formed within the first insulating layer, the via being electrically coupled to the workpiece component portion. A capacitor dielectric is disposed over the capacitor bottom plate, and a capacitor top plate is disposed over the capacitor dielectric.

An optional liner comprising a non-conductive material may be deposited over the first insulating layer to protect the first insulating layer from planarization processes. The use of this optional liner requires a mask and a patterning and etch process to remove the liner from conductive vias and the capacitor bottom electrode in order to make electrical connections.

Advantages of the invention include the fabrication of a MIMcap requiring no additional masks to manufacture it. The MIMcap bottom plate is formed when contact vias are formed, and the MIMcap top plate is formed when conductor lines are formed in a metallization layer, so that the MIMcap bottom and top plates are formed during existing masking and patterning processes. Only one metallization level is used to manufacture the MIMcap, and the process is not dependent on the number of metal layers. The first copper metallization level is deposited after the MIMcap dielectric. This enables the use of a wider variety of dielectric materials for the MIMcap dielectric, and higher temperature processes may be used. The displaced capacitor electrodes (top and bottom plates) inhibit breakdown at the capacitor stack edges.

### BRIEF DESCRIPTION OF THE DRAWINGS

The above features of the present invention will be more clearly understood from consideration of the following descriptions in connection with accompanying drawings in which:

FIGS. 1-9 illustrate cross-sectional views of the MIMcap structure in accordance with a preferred embodiment of the present invention in various stages of fabrication;

FIGS. 10-12 show cross-sectional views of a preferred embodiment of the present invention at various stages of fabrication; and

FIGS. 13-16 show cross-sectional views of a preferred embodiment of the present invention having an additional TiN liner over the MIMcap dielectric at various stages of fabrication.

Corresponding numerals and symbols in the different figures refer to corresponding parts unless otherwise indicated. The figures are drawn to clearly illustrate the relevant aspects of the preferred embodiments, and are not necessarily drawn to scale.

### DETAILED DESCRIPTION OF PREFERRED EMBODIMENTS

Three preferred embodiments of the present invention will be described, followed by a discussion of some advantages of the invention. Only one MIMcap is shown in each figure, although many MIMcaps and other electronic circuit devices may be present within each layer. The term “via” is used herein to describe a portion of conductive material, in the shape of a substantially cylindrical plug, for example, that is formed within an insulating layer to electrically couple an underlying component or conductive line to an overlying component or conductive line in a subsequent layer.

FIGS. 1-9 show cross-sectional views of a MIMcap structure and method of fabrication thereof in accordance with a first embodiment of the present invention. A wafer 10 having a workpiece 12 is provided, typically comprising single-crystal silicon. The workpiece 12 may include oxide layers, conductive layers or other semiconductor elements 16, e.g., transistors or diodes formed in a FEOL, for example. Compound semiconductors such as GaAs, InP, Si/Ge, SiC may be used in place of silicon as a substrate material. A shallow trench isolation (STI) region 14 may be formed in the top surface of the workpiece 12. STI region 14 may also comprise a deep trench isolation region, for example, when used in an erasable dynamic random access memory (eDRAM). STI region 14 may isolate p-wells and n-wells of transistors from one another (not shown).

A liner 18 is deposited, followed by the deposition of dielectric layer 20, as shown in FIG. 1. Liner 18 may comprise a nitride such as SiN, and may alternatively comprise BLOK™, as examples. Dielectric layer 20 may comprise a self-planarizing insulator such as boron phosphorus silicon glass (BPSG), for example, and may alternatively comprise other insulators such as oxide, for example.

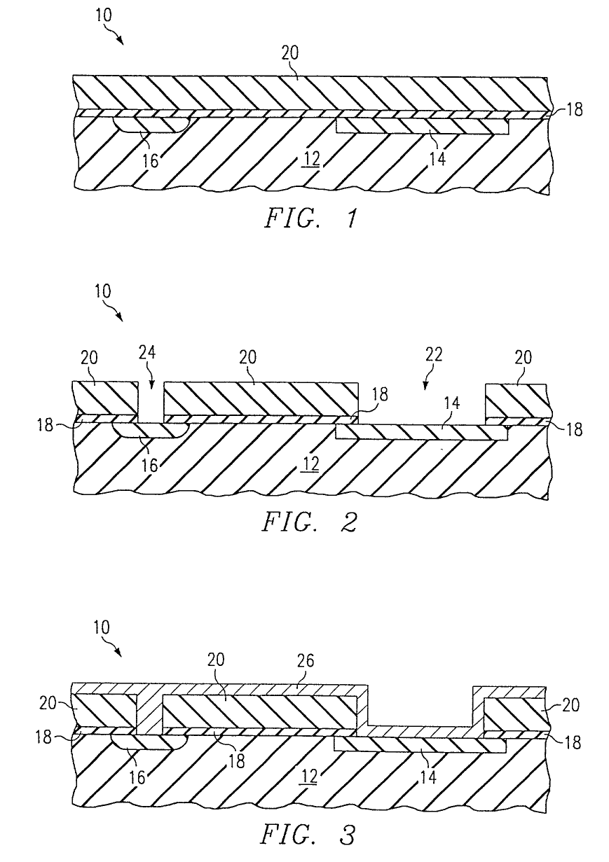

Liner 18 and dielectric layer 20 are patterned with a lithography process and etched to form a trench 22 for a capacitor bottom plate, as shown in FIG. 2. Preferably, a hole 24 for a contact via is simultaneously formed that will couple the workpiece component portion 16 to conductive lines formed in subsequent metallization layers. Hole 24 is simultaneously formed when capacitor bottom plate trench 22 is formed, in accordance with the present invention.

A conductive layer 26 is deposited over dielectric layer 20, via hole 24, and the capacitor bottom plate trench 22, as shown in FIG. 3. Conductive layer 26 preferably comprises tungsten (W), and may alternatively comprise other conductive materials such as copper, aluminum or combinations thereof, as examples.

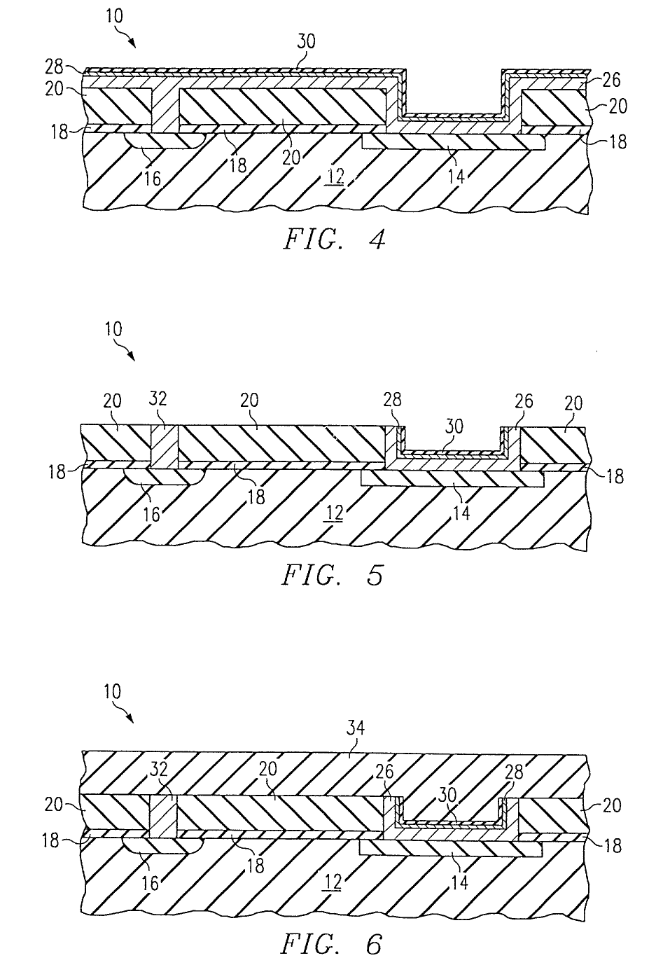

Optional liner 28 comprising TiN, for example, and alternatively comprising TaN, may be deposited over conductive layer 26, as shown in FIG. 4. A capacitor dielectric layer 30 is deposited over liner 28. Capacitor dielectric 30 preferably comprises oxide and may alternatively comprise an insulator such as a nitride, a combination of an oxide and a nitride, or a high dielectric constant material such as Al₂O₃ or TaO₅, as examples. Capacitor dielectric 30 may comprise a dielectric that requires a higher temperature to deposit, e.g. using chemical vapor deposition (CVD) or plasma enhanced chemical vapor deposition (PECVD), in the BEOL, which is an advantage of the present invention. Higher temperature materials and processes may be used because a metallization layer has not been deposited yet.

The wafer 10 is exposed to a chemical-mechanical polishing (CMP) process to remove capacitor dielectric 30, liner 28, and conductive layer 26 from the top surfaces of oxide layer 20, as shown in FIG. 5. Because different chemistries may be required to remove the various material layers, this may take more than one processing step. The surface of the dielectric layer 20 may be “touched up” or etched slightly to further planarize the dielectric layer 20 top surface (not shown).

An insulating layer 34 is deposited over conductive layer 26, liner 28, capacitor dielectric 30, and exposed portions of dielectric layer 20, as shown in FIG. 6. Insulating layer 34 serves as an inter-level dielectric. For the present MIMcap application, insulating layer 34 preferably comprises a low-dielectric constant material, having a dielectric constant k of 3.6 or less, for example. Insulating layer 34 typically comprises an organic spin-on material such as a polyimide, and may also comprise low-k CVD materials such as SiCOH or black diamond, as examples. Insulating layer 34 may comprise a material such as Dow Chemical Corporation's SiLK™ and AlliedSignal Inc.'s Flare™, as examples. Alternatively, insulating layer 34 may comprise an oxide.

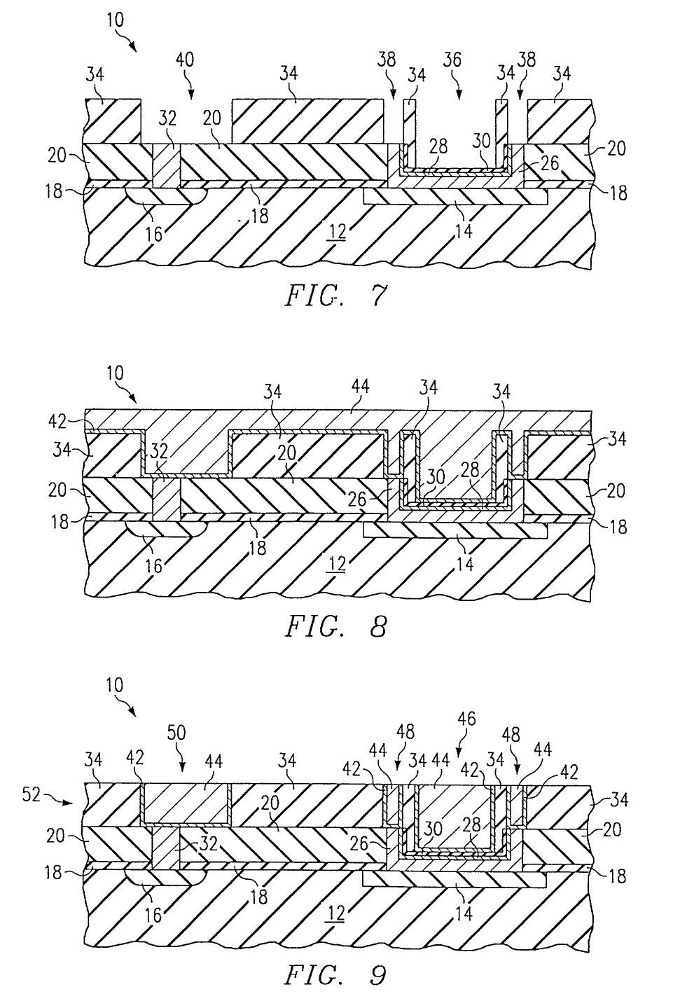

Insulating layer 34 is patterned and etched to form capacitor top plate trenches 36 and trenches 38 that will form vias to electrically couple the capacitor bottom plate 26 to upper metallization layers and conductive lines, as shown in FIG. 7. Preferably, trenches 40 for metal lines are formed simultaneously in the same processing step as the step in which trenches 36 and 38 are formed. Preferably, in accordance with the present invention, insulating layer 34 will have formed within it a major metallization layer, such as M1, M2, etc., to be described further herein. The patterning of insulating layer 34 may comprise a hard mask process, for example.

A metallization liner 42 is deposited and/or plated, as shown in FIG. 8. Conductive material 44 is deposited over liner 42. Conductive material 44 preferably comprises copper, and may alternatively comprise other conductive materials such as aluminum, for example. Metallization liner 42 preferably comprises TaN and may alternatively comprise other liner materials such as TiN, for example.

The wafer 10 is exposed to a CMP process to remove portions of conductive material 44 and metallization liner 42 from the top surfaces of insulating layer 34, as shown in FIG. 9. Portions of conductive layer 44 and metallization liner 42 remain within trench 36 to form MIMcap capacitor top plate 46. Portions of conductive layer 44 remain within trenches 38 to form metal lines 48 that couple to capacitor bottom plate 26. Portions of conductive layer 44 remaining within trench 40 comprise conductive line 50.

The resulting structure shown in FIG. 9 illustrates a MIMcap 52 in accordance with the present invention, comprising capacitor top plate 46, capacitor dielectric 30, and capacitor bottom plate 26. MIMcap 52 is formed within the same insulating layers 20 and 34 as conductor via 32 and conductor line 50, respectively.

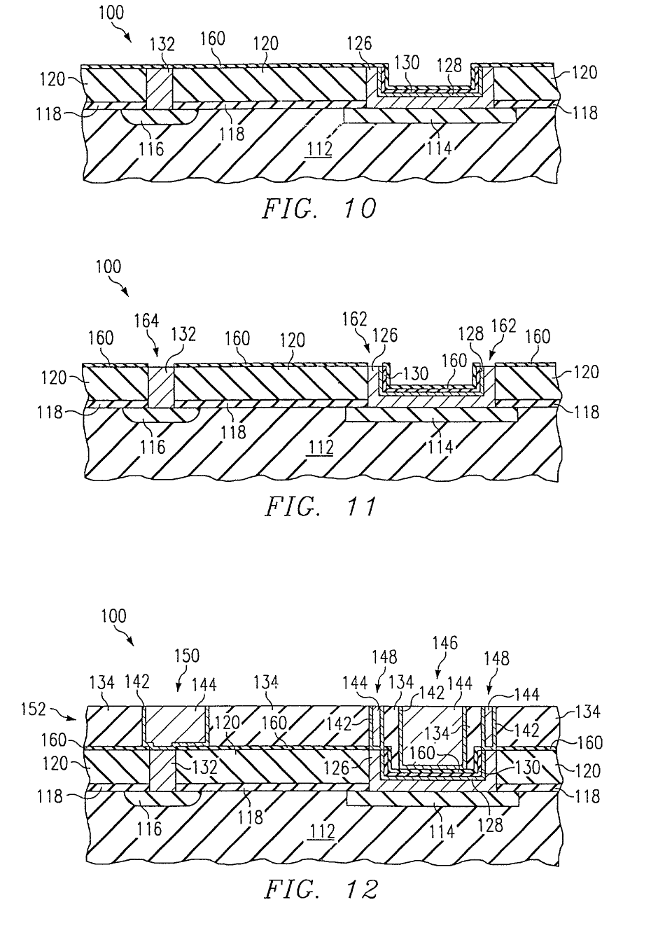

A second preferred embodiment of the present invention is shown in FIGS. 10-12. The same process steps as described for FIGS. 1-5 are followed. A liner 160 is deposited over dielectric layer 120, capacitor dielectric 130, and exposed portions of liner 128 and conductive layer 126, as shown in FIG. 10. Liner 160 preferably comprises a non-conductive material such as a nitride, e.g. SiN.

Liner 160 provides an etch stop material for subsequent processing steps, and provides a barrier layer between the various insulating materials used for dielectric layers 120 and 134. However, because liner 160 is non-conductive, a patterning and etch process must be performed to remove portions of liner 160 from regions 162 and 164 where electrical contact must be made to underlying conductive materials 126, 132, as shown in FIG. 11.

Although the use of liner 160 requires the use of an additional mask, liner 160 is advantageous because it protects dielectric layer 120 during the dielectric 134 etch process, improving the reliability of the MIMcap 152.

Subsequent processing steps are performed on wafer 100 in accordance with those described for FIGS. 6-9, resulting in the MIMcap structure 152 shown in FIG. 12.

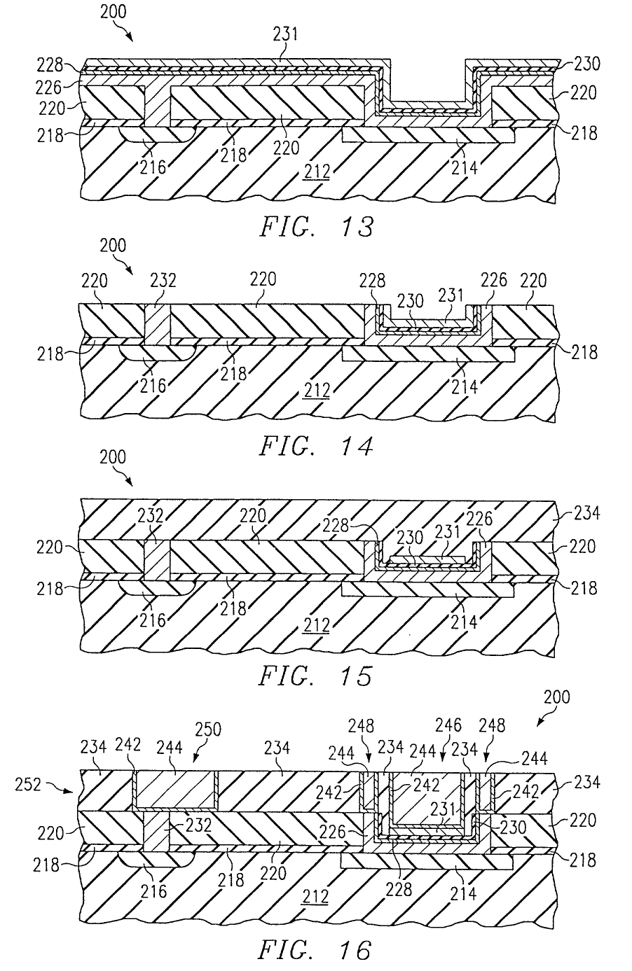

A third preferred embodiment of the present invention is shown in FIGS. 13-16. The same process steps as described for FIGS. 1-4 are followed. A liner 231 is deposited over capacitor dielectric 230, shown in FIG. 13. Liner 231 preferably comprises a conductive material such as a nitride, and more preferably comprises TiN. Liner 231 protects capacitor dielectric 230 during the CMP process and subsequent processing steps.

The wafer 200 is exposed to a CMP process to remove liner 231, capacitor dielectric 230, liner 228, and conductive layer 226 from the top surfaces of oxide layer 220, as shown in FIG. 14.

Liner 231 is patterned, e.g. with a mask, not shown, and etched to leave liner 231 remaining over a portion of the bottom horizontal surface of the capacitor dielectric 230, as shown in FIG. 15. An insulating layer 234 is deposited over conductive layer 226, liner 228, capacitor dielectric 230, and exposed portions of dielectric layer 220, as shown in FIG. 15.

Although the use of liner 231 requires the use of an additional mask, liner 231 is advantageous because it protects capacitor dielectric 230 during subsequent processing steps, improving the reliability of the MIMcap 252.

Subsequent processing steps are performed on wafer 200 in accordance with those described for FIGS. 7-9, resulting in the MIMcap structure 252 shown in FIG. 16.

The novel MIMcap and method of fabrication thereof disclosed herein achieves technical advantages by the fabrication of a MIMcap 52/152/252 requiring no additional masks to manufacture it. The capacitor bottom plate 26/126/226 is formed when contact via 32/132/232 is formed, and capacitor top plate 46/146/246 is formed when conductor line 50/150/250 is formed in a metallization layer, so that the capacitor bottom and top plates are formed during existing masking and patterning processes. Only one metallization level is used to manufacture the MIMcap 52/152/252, and the process is not dependent on the number of metal layers. This enables the use of a wider variety of dielectric materials for the capacitor dielectric 30/130/230, and higher temperature processes can be used. The displaced capacitor electrodes, e.g. top and bottom plates, of the present invention inhibit breakdown at the capacitor stack edges, which can cause field enhancement, leakage current, and reduced reliability in prior art MIMcaps.

A single damascene process has been described herein to describe the conductive line formation. However, alternatively, a dual-damascene or non-damascene process may also be used.

While the invention has been described with reference to illustrative embodiments, this description is not intended to be construed in a limiting sense. Various modifications in combinations of the illustrative embodiments, as well as other embodiments of the invention, will be apparent to persons skilled in the art upon reference to the description. In addition, the order of process steps may be rearranged by one of ordinary skill in the art, yet still be within the scope of the present invention. It is therefore intended that the appended claims encompass any such modifications or embodiments. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of fabricating a metal-insulator-metal (MIM) capacitor, comprising:
providing a workpiece, the workpiece including a substrate portion and a component portion;
depositing a first insulating layer over the workpiece;
etching the first insulating layer to simultaneously form a trench for a capacitor bottom plate over the workpiece substrate portion and form a hole for a via over the workpiece component portion; and
depositing a conductive material to simultaneously fill the capacitor bottom plate trench and the via hole, wherein filling the via hole provides electrical contact to the workpiece component portion.

2. The method according to claim 1, further comprising:
depositing a liner over the first insulating layer, prior to depositing a conductive material.

3. The method according to claim 1, further comprising:
forming a capacitor dielectric over the capacitor bottom plate; and
forming a capacitor top plate over the capacitor dielectric.

4. The method according to claim 3, further comprising:
forming a second insulating layer over the capacitor dielectric; and
etching the second insulating layer to permit the formation of the capacitor top plate, wherein etching the second insulating layer includes etching a hole for a metal line coupled to the capacitor bottom plate.

5. The method according to claim 4, wherein depositing a conductive material includes filling the capacitor bottom plate metal line hole.

6. The method according to claim 5, further comprising removing portions of the conductive material from the top surface of the second insulating layer.

7. The method according to claim 6, further comprising:
depositing a non-conductive liner over the first insulating layer, capacitor bottom plate, and capacitor bottom plate via; and
removing a portion of the non-conductive liner over the capacitor bottom plate via.

8. The method according to claim 6, wherein depositing a conductive material comprises depositing tungsten.

9. The method according to claim 6, wherein forming a capacitor top plate comprises depositing copper.

10. The method according to claim 3, further comprising depositing a nitride liner over the conductive material, prior to forming a capacitor dielectric.

11. The method according to claim 10, further comprising patterning and etching the nitride liner to leave nitride liner on portions of the horizontal surface of the capacitor dielectric.

12. A method of fabricating a metal-insulator-metal (MIM) capacitor, comprising:
depositing a first insulating layer over a workpiece, the workpiece including a substrate portion and a component portion;
simultaneously forming a capacitor bottom plate over the workpiece substrate portion and a via over the workpiece component portion, the via providing electrical contact to the workpiece component portion;
forming a capacitor dielectric over the capacitor bottom plate; and
forming a capacitor top plate over the capacitor dielectric.

13. The method according to claim 12, further comprising depositing a liner over the first insulating layer, prior to depositing a conductive material.

14. The method according to claim 13, further comprising:
forming a second insulating layer; and
etching the second insulating layer, wherein etching the second insulating layer includes etching a hole for a metal line to the capacitor bottom plate.

15. The method according to claim 14, wherein depositing a conductive material includes filling the capacitor bottom plate metal line hole.

16. The method according to claim 15, further comprising removing portions of the conductive material from the top surface of the second insulating layer.

17. The method according to claim 12, further comprising:
depositing a non-conductive liner over the first insulating layer, capacitor bottom plate, and capacitor bottom plate via; and
removing a portion of the non-conductive liner over the capacitor bottom plate via.

18. The method according to claim 12, further comprising depositing a nitride liner over the conductive material, prior to forming a capacitor dielectric.

19. The method according to claim 18, further comprising patterning and etching the nitride liner to leave nitride liner on portions of the horizontal surface of the capacitor dielectric.

20. A metal-insulator-metal (MIM) capacitor, comprising:
a workpiece, the workpiece including a substrate portion and a component portion;
a first insulating layer disposed over the workpiece;
a capacitor bottom plate formed within the first insulating layer over the workpiece substrate portion;
a via formed within the first insulating layer, the via electrically coupled to the workpiece component portion;
a capacitor dielectric disposed over the capacitor bottom plate; and
a capacitor top plate disposed over the capacitor dielectric.

21. The MIM capacitor according to claim 20, further comprising:
a second insulating layer disposed over the capacitor dielectric, wherein the capacitor top plate is formed within the second insulating layer; and
a capacitor bottom plate via formed within the second insulating layer coupled to the capacitor bottom plate.

22. The MIM capacitor according to claim 21, further comprising a non-conductive liner over the capacitor bottom plate.

23. The MIM capacitor according to claim 21, further comprising a TiN liner over a horizontal portion of the capacitor bottom plate.

24. The MIM capacitor according to claim 21, wherein the capacitor bottom plate comprises tungsten and the capacitor top plate comprises copper.
